(19) United States
(12) Patent Application Publication
(10) Pub. No.: US 2008/0194112 A1
(43) Pub. Date: Aug. 14, 2008

(54) METHOD AND SYSTEM FOR PLASMA ETCHING HAVING IMPROVED ACROSS-WAFER ETCH UNIFORMITY

(75) Inventors: Qingyun Yang, Poughkeepsie, NY (US); Joyce C. Liu, Carmel, NY (US); Hongwen Yan, Somers, NY (US); Ying Zhang, Yorktown Heights, NY (US)

Correspondence Address: CANTOR COLBURN LLP - IBM FISHKILL, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/673,128

(22) Filed: Feb. 9, 2007

(51) Int. Cl. H01L 21/3065

(52) U.S. Cl. 438/710; 156/345.33; 257/E21.218

(57) ABSTRACT

A method for improving across-wafer etch uniformity of semiconductor devices in an etching chamber, wherein the method includes: introducing a first flow of gas mixtures from a central gas distribution plate manifold; introducing a second flow of gas mixtures from an auxiliary gas feed; and controlling process parameters including one or more of: duration, power, pressure, and gas flow rates for the first and second flow of gas mixtures; wherein the central gas distribution plate manifold is positioned above the semiconductor wafer; wherein the auxiliary gas feed is positioned around the perimeter of the semiconductor wafer; and wherein the controlling of the process parameters of the central gas distribution plate manifold and the auxiliary gas feed is facilitated by independent controls.

### TRADEMARKS

IBM® is a registered trademark of International Business Machines Corporation, Armonk, N.Y., U.S.A. Other names used herein may be registered trademarks, trademarks or product names of International Business Machines Corporation or other companies.

### BACKGROUND OF THE INVENTION

1. Field of the Invention

This invention relates generally to plasma etching of semiconductor devices, and more particularly, to a method and system for improving across-wafer etch uniformity.

2. Description of the Related Art

As semiconductor technology continues to advance, the demands on the manufacturing process of semiconductor devices increase as well. In particular, larger wafer sizes allow for an increased number of semiconductor chip devices for a given manufacturing run, thereby lowering unit costs of the individual semiconductor devices. Uniformity in layers and substrate features are a critical production requirement. However, as wafers sizes increase it becomes more difficult to insure a uniform process across the wafer surface. Etch processes generally exhibit variation (etch rate and/or critical dimension) as a function of the radial distance from the wafer center.

Etching chamber designs with dual zone temperature electrostatic chuck (“E-Chuck”) or dual zone gas feeds have contributed to minimize non-uniformity of wafer etch. However, as seen in FIG. 1 a radial distribution of a gate feature critical dimension obtained with a plasma etcher with a dual zone E-Chuck still shows a significant variation. In particular, FIG. 1 illustrates a 5 nm etch bias increase as the radial distance from the wafer center increases from r=120 mm to r=140 mm for a 90 nm gate feature produced with a reactive ion etching (RIE) process. The problem of non-uniformity becomes progressively worse for large diameter wafers (300 mm and 450 mm), thus there is a critical need for innovative solutions for improving uniformity across the surface of large diameter wafers.

### SUMMARY OF THE INVENTION

A method for improving across-wafer etch uniformity of semiconductor devices in an etching chamber, includes: introducing a first flow of gas mixtures from a central gas distribution plate manifold; introducing a second flow of separate gas mixtures from an auxiliary gas feed; controlling process parameters including one or more of: duration, and gas flow rates for the first and second flows of gas mixtures; wherein the central gas distribution plate manifold is positioned above the semiconductor wafer; wherein the auxiliary gas feed is positioned around the perimeter of the semiconductor wafer; and wherein the controlling of the process parameters of the central gas distribution plate manifold and the auxiliary gas feed is facilitated by independent controls.

A system for improving across-wafer etch uniformity in an etching chamber, includes: a central gas distribution plate manifold with a first flow of gas mixtures controlled by a first controller; an auxiliary gas feed with a second flow of gas mixtures controlled by a second controller; and wherein the central gas distribution plate manifold is positioned above a semiconductor wafer under process in the etching chamber; wherein the auxiliary gas feed is positioned around the perimeter of the semiconductor wafer; and wherein the first and second controllers independently control process parameters including one or more of: duration, and gas flow rates for each component of gases within each of the two gas mixtures for the first and second etching gas flows.

A plasma reaction chamber for processing of semiconductor wafers including: a gas distribution plate having a plurality of apertures sized, shaped, and positioned to deliver at least one gas to a central portion of a semiconductor wafer operatively positioned within the reaction chamber; a second gas distribution ring having a plurality of apertures sized, shaped, and positioned to deliver at least one gas to an outer radial portion of the semiconductor wafer; and wherein the flow of the at least one gas through the gas distribution plate and the gas distribution ring is independently controllable.

Additional features and advantages are realized through the techniques of the present invention. Other embodiments and aspects of the invention are described in detail herein and are considered a part of the claimed invention. For a better understanding of the invention with advantages and features, refer to the description and to the drawings.

### BRIEF DESCRIPTION OF THE DRAWINGS

The subject matter that is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 illustrates a 5 nm etch bias increase as the radial distance from the wafer center increases from r=120 mm to r=140 mm for a 90 nm gate feature produced with a reactive ion etching process.

FIG. 2 illustrates a plasma etcher with a showerhead gas feed.

FIG. 3 illustrates a system for practicing one or more embodiments of the present invention.

The detailed description explains the preferred embodiments of the invention, together with advantages and features, by way of example with reference to the drawings.

### DETAILED DESCRIPTION

Embodiments of the present invention provide a method and system for improving across-wafer etch uniformity of semiconductor devices by providing an edge proximity auxiliary gas feed design. The plasma etcher embodied in the present invention provides both a central gas distribution plate manifold, as well as a circumferential gas distribution ring manifold positioned proximate the outer edge of a wafer undergoing plasma etching. Gas flows through the two plasma gas distribution manifolds are independently controllable. Providing two independently controllable manifolds provides greater uniformity of the etching process across the entire surface of wafer.

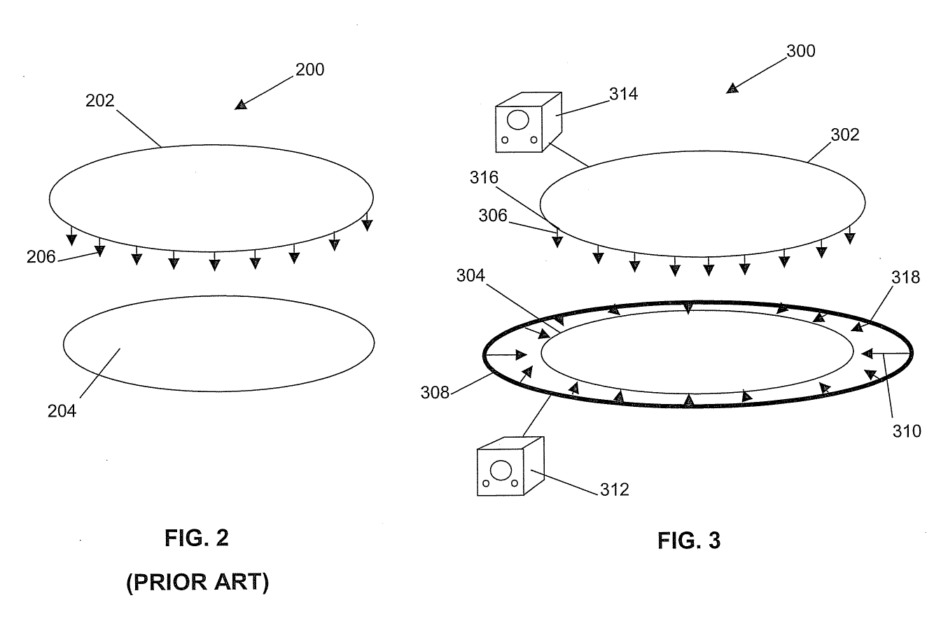

FIG. 2 illustrates a conventional plasma etcher 200 with a central gas distribution plate manifold 202 positioned above a wafer 204 under process. The central gas distribution plate manifold 202 directs an etching gas flow 206 toward the wafer 204.

FIG. 3 illustrates an embodiment of the present invention of a plasma etcher 300 with a central gas distribution plate manifold 302 positioned above a wafer 304 under process. The central gas distribution plate manifold 302 act as the primary gas feed into the plasma etcher 300, and directs an etching gas flow 306 toward the wafer 304 through a plurality of apertures 316 sized, shaped, and positioned to deliver at least one gas to a central portion of the wafer 304. An edge proximity auxiliary gas feed/gas distribution ring 308 consisting of a ring of orifices or apertures 318 that feed an auxiliary gas stream 310 toward the wafer 304. The plurality of apertures 318 are sized, shaped, and positioned to deliver at least one gas to an outer radial portion of the wafer 304. The edge proximity auxiliary gas feed/gas distribution ring 308 is located at a small distance from the wafer 304 edge. Controller 312 independently controls the edge proximity auxiliary gas feed/gas distribution ring 308, while the central gas distribution plate manifold/electrode 302 is controlled by controller 314. The separate controllers (312, 314) facilitate the separate gas mixtures (306, 310) to flow at rates independent of each other.

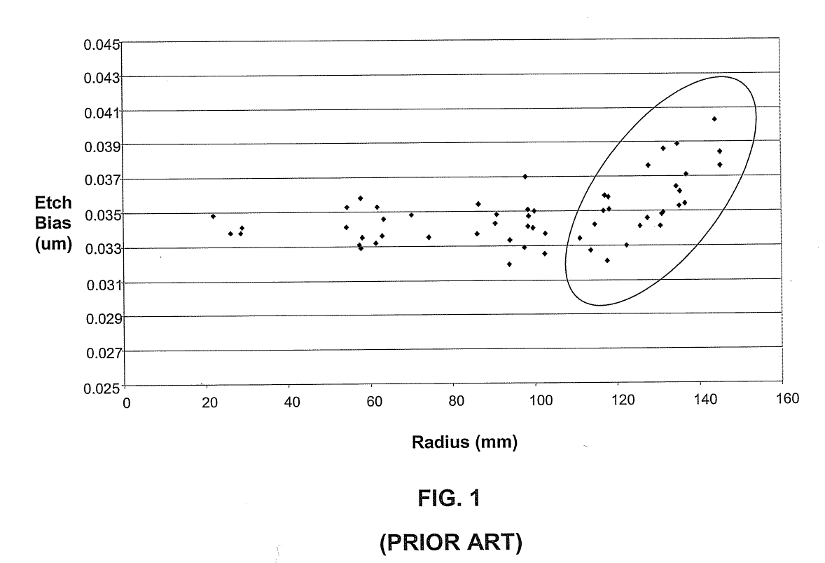

Examples of applying embodiments of the present invention for gate etch critical dimension (CD) improvement are as follows:
A) For polysilicon etch steps during a polysilicon gate etch process, a flow of oxygen (O₂) from the edge proximity auxiliary gas feed/electrode 308 can cause a small increase in the taper angle of the gate etch feature, and therefore a decrease in etch bias relative to the wafer center. This can compensate for the high etch bias near the wafer edge as shown in FIG. 1.
B) A small amount of carbon-hydrogen (C₂H₄) flow from the edge proximity auxiliary gas feed/gas distribution ring 308 during antireflective coating (ARC) and trim steps can improve resist erosion and lower the CD trim rate at the edge of the wafer 304 and compensate for the high etch CD bias at the wafer edge.
C) A small amount of carbon fluoride (C₄F₈) flow from the edge proximity auxiliary gas feed/gas distribution ring 308 can improve on the n+ doped poly profile, which tends to show an increased necking at the wafer edge.

The flow diagrams depicted herein are just examples. There may be many variations to these diagrams or the steps (or operations) described therein without departing from the spirit of the invention. For instance, the steps may be performed in a differing order, or steps may be added, deleted or modified. All of these variations are considered a part of the claimed invention.

While the preferred embodiments to the invention has been described, it will be understood that those skilled in the art, both now and in the future, may male various improvements and enhancements which fall within the scope of the claims which follow. These claims should be construed to maintain the proper protection for the invention first described.

What is claimed is:

1. A method for improving across-wafer etch uniformity of semiconductor devices in an etching chamber, wherein the method comprises:
introducing a first flow of gas mixtures from a central gas distribution plate manifold;
introducing a second flow of gas mixtures from a circumferential gas distribution ring manifold; and
controlling process parameters including one or more of: duration, power, pressure, and gas flow rates for the first and second flow of gas mixtures;
wherein the central gas distribution plate manifold is positioned above a semiconductor wafer undergoing plasma etching;
wherein the circumferential gas distribution ring manifold is positioned proximate the outer edge of the wafer undergoing plasma etching; and
wherein the controlling of the process parameters of the central gas distribution plate manifold and the circumferential gas distribution ring manifold is facilitated by independent controls.

2. (canceled)

3. A system for improving across-wafer etch uniformity of semiconductor devices in an etching chamber, comprising:
a central gas distribution plate manifold with a first flow of gas mixtures controlled by a first controller; and
an auxiliary gas feed with a second flow of gas mixtures controlled by a second controller;
wherein the central gas distribution plate manifold is positioned above a semiconductor wafer undergoing plasma etching in the etching chamber;
wherein the auxiliary gas feed is a circumferential gas distribution ring manifold positioned proximate the outer edge of the wafer undergoing plasma etching; and
wherein the first and second controllers independently control process parameters including one or more of: duration and gas flow rates for each component gas within each of the first and second flow of gas mixtures.

4. (canceled)

5. A plasma reaction chamber for processing of semiconductor wafers comprising:
a gas distribution plate having a plurality of apertures sized, shaped, and positioned to deliver at least one gas to a central portion of a semiconductor wafer operatively positioned within the reaction chamber;
a gas distribution ring having a plurality of apertures sized, shaped, and positioned to deliver at least one gas to an outer radial portion of the semiconductor wafer; and
wherein the flow of the at least one gas through the gas distribution plate and the gas distribution ring is independently controllable.
